(19) United States
(12) Patent Application Publication
(10) Pub. No.: US 2003/0141992 A1
(43) Pub. Date: Jul. 31, 2003

(54) Shiftless double stroke keyboard and word processor for computers

(76) Inventor: John Splawn Page, Silverado, CA (US)

Correspondence Address: JOHN SPLAWN PAGE JR., 25092 Farthing # 61, Lake Forest, CA, 92630, US

(21) Appl. No.: 10/059,981

(22) Filed: Jan. 30, 2002

(51) Int. Cl. H03M 11/00; H03K 17/94

(52) U.S. Cl. 341/22

(57) ABSTRACT

THE SHIFTLESS DOUBLE STROKE KEYBOURD AND WORD PROCESSOR FOR COMPUTERS will type a lower case letter when a keyboard key it is struck once and it will type a capital letter if that key is struck twice. When two lower case letters are desired as in the word better, the key is held down slightly longer to cause a repeat of that letter. The same double stroke technique is used to type the number keys. One stroke types a number and holding the key down slightly longer gives repeats of that number. The same double stroke technique is used to type the symbols on the lower and upper part of the symbol keys; the typist strikes the key once for the lower symbol and strikes that key a second time to get the upper symbol.

### BACKGROUND OF THE INVENTION

Many people who are not experienced at typing are slowed down and annoyed at having to move their finger position to the shift key to get a capital letter. Microsoft thought this annoyance was significant enough to incorporate a feature now included in their WORD processing program that automatically gives a capital letter after a period is typed. However there are a number of situations where a capital letter is desired where there isn't a period typed before the desired capital letter. Also, all of the number keys and the 11 keys that have two symbols on them require the shift key to be depressed in order to get the upper symbol.

The basic typing technique that is universally taught is to have the four fingers of each hand in a starting position with the tips of the fingers in touch with four keys by each hand. If the fingers can stay in relative constant touch with these keys, the typist is less likely to lose his proper position on the keyboard. Having to use both hands to type a capital letter or a symbol that require having to pull one's little finger down and away to reach the shift key causes a slight loss of position with the other keys. It also causes a strain on the wrist if the typist try's to maintain his fingers close the proper position close to the keys. This contributes to Carpal Tunnel irritation, which has become a serious disability problem.

### OBJECT OF THE INVENTION

The object of applicant's invention is to make a word processor, keyboard and computer easier to use when typing capital letters and the symbols on keys that require the use of the shift key. Actually, the goal is to provide a word processor and keyboard for a computer that is a SHIFTLESS system. No shift key is needed. Therefore, this system should decrease the incidence of Carpal Tunnel stress, strain and disabilities inflicting too many people.

### SUMMARY

The SHIFTLESS KEYBOARD AND WORD PROCESSOR FOR COMPUTERS is easier to use when typing capital letters and the upper symbols on the keys that require the use of the shift key. Actually, it is a word processor and keyboard that is a SHIFTLESS system. No shift key is needed. It will type a lower case letter if a key is struck once and it will type a capital letter if that key is struck twice. When two lower case letters are desired as in the word better, the “t” key is held down slightly longer to cause a repeat of that letter. The same double stroke technique is used to type the number keys. One stroke types a number and holding the key down slightly longer gives repeats of that number. To get the upper symbols on the number key, the typist strikes the key a second time. The dash and underscore work the same way.

### DETAILED DESCRIPTION

The shiftless system is a computer word processor program and keyboard with typing keys and a wire or wireless means of transmitting electronic signals from said keys on said keyboard to said word processor and said computer whereby, when the keyboard keys are struck once they send electronic signals in the form of a series of numerical relationships (termed routines) to the word processor which interprets said electronic signals and enters the information in the signal to cause the word processor and computer to enter or type a lower case letter when a key is struck once and when that key is struck twice, it types that letter as a capital letter. It also will type one or the other of the two symbols that are on many of the keys, either the lower symbol or the upper symbol, whereby when a key is struck once, one of the symbols on the key is typed and when that key is struck twice, the other symbol on that key is typed. The speed of the repeat rate can be adjusted on the keyboard in the control panel to get the speed of repeat that a person wants so that it will repeat just two times easily and not more if you don't hold the key down too long.

There are two adjustments that should be made on the keyboard. One is the REPEAT DELAY and the other is the REPEAT RATE. Adjusting the REPEAT RATE to Slow is perfect. Adjusting the REPEAT DELAY to Fast is perfect.

1. A word processor program for a computer, a keyboard with typing keys and a wire or wireless means of transmitting electronic signals from said keys on said keyboard to said word processor and said computer whereby, when the keyboard keys are struck once they send electronic signals in the form of a series of numerical relationships (termed routines) to the word processor which interprets said electronic signals and enters the information in the signals to cause the word processor and computer to enter or type a lower case letter when a key is struck once and when that key is struck twice, it types that letter as a capital letter.

2. A word processor program for a computer, a keyboard with typing keys and a wire or wireless means of transmitting electronic signals from said keys on said keyboard to said word processor and said computer whereby, when the keyboard keys are struck once they send electronic signals in the form of a series of numerical relationships (termed routines) to the word processor which interprets said electronic signals and enters the information in the signals to cause the word processor and computer to type one or the other of the two symbols that are on many of the keys, either a lower symbol or an upper symbol, whereby when a key is struck once, one of the symbols on the key is typed and when that key is struck twice, the other symbol on that key is typed.
